(19) United States
(12) Patent Application Publication
(10) Pub. No.: US 2025/0219607 A1
(43) Pub. Date: Jul. 3, 2025

(54) TEMPERATURE COMPENSATED BULK ACOUSTIC WAVE DEVICE

(71) Applicant: Skyworks Global Pte. Ltd., Singapore (SG)

(72) Inventors: Ahmed E. Hassanien, Savoy, IL (US); Kwang Jae Shin, Yongin-si (KR)

(21) Appl. No.: 18/977,088

(22) Filed: Dec. 11, 2024

Related U.S. Application Data
(60) Provisional application No. 63/615,475, filed on Dec. 28, 2023.
(60) Provisional application No. 63/615,511, filed on Dec. 28, 2023.

(51) Int. Cl. H03H 9/02; H03H 3/02; H03H 9/17; H03H 9/56

(52) U.S. Cl. CPC H03H 9/02102; H03H 3/02; H03H 9/173; H03H 9/568

(57) ABSTRACT

A bulk acoustic wave device is disclosed. The bulk acoustic wave device can include a first electrode, a second electrode including a first layer and a second layer, a piezoelectric layer between the first and second electrodes, and a temperature compensation layer between the first and second layers of the second electrode.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/615,475, filed Dec. 28, 2023, titled “TEMPERATURE COMPENSATED BULK ACOUSTIC WAVE DEVICE,” and U.S. Provisional Patent Application No. 63/615,511, filed Dec. 28, 2023, titled “BULK ACOUSTIC WAVE DEVICE WITH TEMPERATURE COMPENSATION LAYER,” are hereby incorporated by reference under 37 CFR 1.57 in their entirety.

### BACKGROUND

### Technical Field

Embodiments of this disclosure relate to acoustic wave devices, and in particular, to bulk acoustic wave devices with a bonding layer.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed. A bulk acoustic wave resonator can include a set of metal electrodes deposited on opposite surfaces of a piezoelectric material, generating a bulk acoustic wave within the volume of the piezoelectric material. The interaction between the electrodes and the piezoelectric material results in the formation and propagation of a bulk acoustic wave.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a bulk acoustic wave device including: a first electrode; a second electrode including a first layer and a second layer; a piezoelectric layer between the first and second electrodes; and a temperature compensation layer between the first and second layers of the second electrode.

In some embodiments, the techniques described herein relate to a bulk acoustic wave device wherein the piezoelectric layer is in contact with the first electrode and the first layer of the second electrode.

In some embodiments, the techniques described herein relate to a bulk acoustic wave device wherein the second layer is electrically floating.

In some embodiments, the techniques described herein relate to a bulk acoustic wave device wherein the second layer is electrically connected to the first layer.

In some embodiments, the techniques described herein relate to a bulk acoustic wave device wherein the first layer and the second layer include the same material.

In some embodiments, the techniques described herein relate to a bulk acoustic wave device wherein the first layer and the second layer have different thicknesses.

In some embodiments, the techniques described herein relate to a bulk acoustic wave device further including a passivation layer over the second layer such that the second layer is positioned between the temperature compensation layer and the passivation layer.

In some embodiments, the techniques described herein relate to a bulk acoustic wave device wherein the temperature compensation layer includes silicon oxide.

In some embodiments, the techniques described herein relate to a bulk acoustic wave device wherein the temperature compensation layer has a thickness in a range between 5 nanometers and 300 nanometers.

In some embodiments, the techniques described herein relate to a bulk acoustic wave device wherein the first electrode includes a third layer and a fourth layer, the third layer is in contact with the piezoelectric layer and a second temperature compensation layer is disposed between the third and fourth layers.

In some embodiments, the techniques described herein relate to a bulk acoustic wave device wherein thicknesses of the piezoelectric layer and the temperature compensation layer are configured to excite a fundamental mode as a main mode.

In some embodiments, the techniques described herein relate to a bulk acoustic wave device wherein thicknesses of the piezoelectric layer and the temperature compensation layer are configured to excite an overtone mode as a main mode.

In some embodiments, the techniques described herein relate to a bulk acoustic wave device wherein a resonant frequency of the overtone mode is in a range from 5 gigahertz to 12 gigahertz.

In some embodiments, the techniques described herein relate to a bulk acoustic wave device wherein the overtone mode is a second overtone mode.

In some aspects, the techniques described herein relate to a method of forming a bulk acoustic wave device, the method including: providing a first electrode; providing a piezoelectric layer over the first electrode; providing a second electrode including a first layer and a second layer such that the piezoelectric layer is positioned between the first and second electrodes; and providing a temperature compensation layer between the first and second layers of the second electrode.

In some embodiments, the techniques described herein relate to a method wherein providing the temperature compensation layer includes depositing the temperature compensation layer over the first layer of the second electrode.

In some embodiments, the techniques described herein relate to a method wherein the temperature compensation layer includes silicon oxide.

In some embodiments, the techniques described herein relate to a method further including providing a passivation layer over the second layer such that the second layer is positioned between the temperature compensation layer and the passivation layer.

In some embodiments, the techniques described herein relate to a method wherein the piezoelectric layer contacts the first layer of the second electrode.

In some embodiments, the techniques described herein relate to a method wherein the piezoelectric layer contacts the first layer of the second electrode.

In some aspects, the techniques described herein relate to a bulk acoustic wave device including: a first electrode structure; a second electrode structure including a first layer, a second layer, and an intervening layer between the first layer and the second layer; and a piezoelectric layer between the first and second electrode structures, the piezoelectric layer physically isolated from the intervening layer.

In some embodiments, the techniques described herein relate to a bulk acoustic wave device wherein the intervening layer is positioned outside of a region between the first layer and the first electrode structure.

In some embodiments, the techniques described herein relate to a bulk acoustic wave device wherein the intervening layer includes a material that has a positive temperature coefficient of frequency.

In some embodiments, the techniques described herein relate to a bulk acoustic wave device wherein the piezoelectric layer is in contact with the first electrode structure and the first layer of the second electrode structure.

In some embodiments, the techniques described herein relate to a bulk acoustic wave device wherein the second layer is electrically floating.

In some embodiments, the techniques described herein relate to a bulk acoustic wave device wherein the second layer is electrically connected to the first layer.

In some embodiments, the techniques described herein relate to a bulk acoustic wave device further including a passivation layer over the second layer such that the second layer is positioned between the intervening layer and the passivation layer.

In some embodiments, the techniques described herein relate to a bulk acoustic wave device wherein the intervening layer has a thickness in a range between 5 nanometers and 300 nanometers.

In some embodiments, the techniques described herein relate to a bulk acoustic wave device wherein the first electrode structure includes a third layer and a fourth layer, the third layer is in contact with the piezoelectric layer and a second temperature compensation layer is disposed between the third and fourth layers.

In some embodiments, the techniques described herein relate to a bulk acoustic wave device wherein thicknesses of the piezoelectric layer and the intervening layer are configured to excite a fundamental mode as a main mode.

In some embodiments, the techniques described herein relate to a bulk acoustic wave device wherein thicknesses of the piezoelectric layer and the intervening layer are configured to excite an overtone mode as a main mode.

In some embodiments, the techniques described herein relate to a bulk acoustic wave device wherein a resonant frequency of the overtone mode is in a range from 5 gigahertz to 12 gigahertz.

In some aspects, the techniques described herein relate to a bulk acoustic wave device including: a first electrode structure; a second electrode structure including a first layer, a second layer, and an intervening layer between the first layer and the second layer; and a piezoelectric layer between the first and second electrode structures, the intervening layer positioned outside of a region between the first layer and the first electrode structure.

In some embodiments, the techniques described herein relate to a bulk acoustic wave device wherein the intervening layer includes a material that has a positive temperature coefficient of frequency.

In some embodiments, the techniques described herein relate to a bulk acoustic wave device wherein the piezoelectric layer is in contact with the first electrode structure and the first layer of the second electrode structure.

In some embodiments, the techniques described herein relate to a bulk acoustic wave device wherein the second layer is electrically floating.

In some embodiments, the techniques described herein relate to a bulk acoustic wave device wherein the second layer is electrically connected to the first layer.

In some aspects, the techniques described herein relate to a method of forming a bulk acoustic wave device, the method including: providing a first electrode structure; providing a piezoelectric layer over the first electrode structure; and providing a second electrode structure such that the piezoelectric layer is positioned between the first and second electrode structures, the second electrode structure including a first layer, a second layer, and an intervening layer between the first layer and the second layer, the piezoelectric layer physically isolated from the intervening layer.

In some embodiments, the techniques described herein relate to a method wherein the intervening layer positioned outside of a region between the first layer and the first electrode structure.

In some embodiments, the techniques described herein relate to a method further including providing a passivation layer over the second layer such that the second layer is positioned between the intervening layer and the passivation layer.

### BRIEF DESCRIPTION OF THE DRAWINGS

Embodiments of this disclosure will now be described, by way of non-limiting example, with reference to the accompanying drawings.

FIG. 1 is a schematic cross-sectional side view of a bulk acoustic wave (BAW) device according to an embodiment.

FIG. 2 is a schematic cross-sectional side view of a bulk acoustic wave (BAW) device according to another embodiment.

FIG. 3 is a schematic cross-sectional side view of the BAW device of FIG. 1 disposed on a support structure as an example of a film bulk acoustic wave resonator (FBAR).

FIG. 4 is a schematic cross-sectional side view of the BAW device of FIG. 1 disposed on a support structure as an example of a BAW solidly mounted resonator (SMR).

FIG. 5 is a schematic cross-sectional side view of the BAW device of FIG. 2 disposed on a support structure as an example of a film bulk acoustic wave resonator (FBAR).

FIG. 6 is a graph showing a simulated frequency response of a BAW device according to an embodiment.

FIG. 7 is a schematic diagram of an example of an acoustic wave ladder filter.

FIG. 8A is a schematic diagram of an example of a duplexer.

FIG. 8B is a schematic diagram of an example of a multiplexer.

FIG. 9 is a schematic block diagram of a module that includes an antenna switch and duplexers that include one or more bulk acoustic wave devices.

FIG. 10A is a schematic block diagram of a module that includes a power amplifier, a radio frequency switch, and duplexers that include one or more bulk acoustic wave devices.

FIG. 10B is a schematic block diagram of a module that includes a low noise amplifier, a radio frequency switch, and acoustic wave filters that include one or more bulk acoustic wave devices.

FIG. 11 is a schematic block diagram of a module that includes a power amplifier, a radio frequency switch, a duplexer that includes one or more bulk acoustic wave devices.

FIG. 12A is a schematic block diagram of a wireless communication device that includes filters that include one or more bulk acoustic wave devices.

FIG. 12B is a schematic block diagram of another wireless communication device that includes filters that include one or more bulk acoustic wave devices.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with bulk acoustic wave (BAW) devices. A film acoustic wave resonator (FBAR) and a BAW solidly mounted resonator (SMR) are examples of BAW devices.

Heat can be generated during operation of the BAW devices. Relatively high temperatures in BAW devices can lead to problems such as frequency drift, instability, phase noise, material degradation, and thermal expansion mismatch. Therefore, temperature compensation in the BAW devices can be significant. For example, a temperature compensation layer (e.g., a silicon oxide layer) can be positioned between an electrode and a piezoelectric layer of a BAW device to mitigate temperature increase in the BAW device. The temperature compensation layer can bring the temperature coefficient of frequency (TCF) of the BAW device closer to zero. The temperature compensation layer can have a positive temperature coefficient of elasticity. The temperature compensation layer can be in physical contact with the piezoelectric layer and/or the electrode of the BAW device.

However, there are technical challenges and/or drawbacks when implementing a temperature compensation layer between an electrode and a piezoelectric layer of a BAW device. For example, it may be preferable to make the temperature compensation layer relatively thin, but it may not be readily manufacturable to make the temperature compensation layer sufficiently thin for certain frequencies. Also, because the temperature compensation layer may need to be thin in such a structure, the temperature compensation effect can be limited. Further, adding the temperature compensation layer positioned between the electrode and the piezoelectric layer in the BAW device can degrade a coupling coefficient k² as compared to a BAW device without the temperature compensation layer because the temperature compensation layer between the electrode and the piezoelectric layer has an electric field. The coupling coefficient k² can degrade more when the temperature compensation layer is thicker.

Various embodiments disclosed herein relate to bulk acoustic wave (BAW) devices with a temperature compensation layer that provides a relatively high coupling coefficient k² as compared to a BAW device that includes a temperature compensation layer positioned between the electrode and the piezoelectric layer. A BAW device according to an embodiment can include a first electrode, a second electrode that includes a first layer and a second layer, a piezoelectric layer between the first and second electrodes, and a temperature compensation layer between the first and second layers of the second electrode. At least The first layer, the second layer, and the temperature compensation layer can together define a second electrode structure. In some embodiments, the first and second electrodes can be referred to as a bottom electrode and a top electrode, respectively. There can be no electric field applied to the temperature compensation layer or a significantly lower electric field applied to the temperature compensation layer as compared to the piezoelectric layer as the temperature compensation layer is not disposed between the first electrode and the second electrode structure. In some embodiments, the temperature compensation layer can be physically isolated from the piezoelectric layer. The temperature compensation layer can be relatively thick. A thicker temperature compensation layer can contribute to easier manufacturing and better temperature compensation. Separation of the second electrode into multiple layers (e.g., the first and second layers) and positioning the temperature compensation layer between the first and second layers of the second electrode can enable the BAW device to have an improved temperature coefficient of frequency (TCF) and the coupling coefficient k² as compared to a BAW device without a temperature compensation layer or a BAW device with a temperature compensation layer between the piezoelectric layer and an electrode.

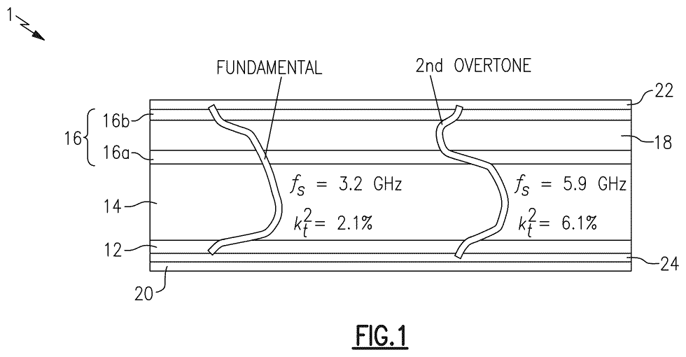

FIG. 1 is a schematic cross-sectional side view of a bulk acoustic wave (BAW) device 1 according to an embodiment. FIG. 1 also shows example wave shapes of a fundamental mode and a second overtone mode in the BAW device 1. The BAW device 1 can include a first electrode 12, a piezoelectric layer 14 over the first electrode 12, and a second electrode 16 over the piezoelectric layer 14. The second electrode 16 can include a first layer 16a and a second layer 16b. The BAW device 1 can also include a temperature compensation layer 18 between the first and second layers 16a, 16b, a first passivation layer 20, a second passivation layer 22, and a seed layer 24 between the first passivation layer 20 and the first electrode 12. The first layer 16a, the second layer 16b, and the temperature compensation layer 18 can together at least partially define a second electrode structure.

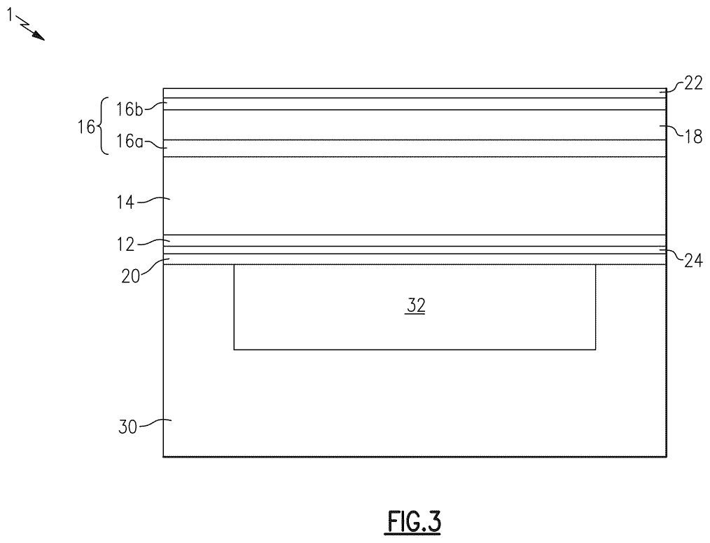

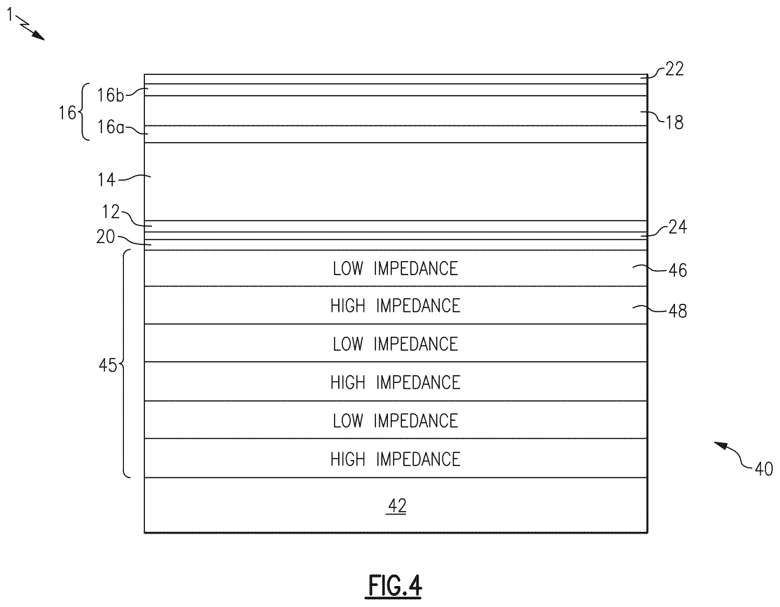

The BAW device 1 shown in FIG. 1 can be supported by a support structure (see FIGS. 3 and 4). The support structure can have a multi-layer structure. For example, the support structure can include a support substrate (e.g., a semiconductor substrate such as a silicon substrate), a trap rich layer, a passivation layer, or one or more intermediate layers therebetween. In some embodiments, a cavity can be formed with the support structure or between the support substrate and the first electrode 12. The cavity can be an air cavity and the BAW device 1 can be a film bulk acoustic wave resonator (FBAR). In some other embodiments, there can be a solid acoustic mirror and the BAW device 1 can be a BAW solidly mounted resonator (SMR).

The first electrode 12 can have a relatively high acoustic impedance. The first electrode 12 can include molybdenum (Mo), tungsten (W), ruthenium (Ru), chromium (Cr), iridium (Ir), platinum (Pt), Ir/Pt, or any suitable alloy and/or combination thereof. The second electrode 16 can have a relatively high acoustic impedance. The second electrode 16 can include Mo, W, Ru, Cr, Ir, Pt, Ir/Pt, or any suitable alloy and/or combination thereof. The second electrode 16 can be formed of the same material as the first electrode 12 in certain instances. The thickness of the first electrode 12 can be approximately the same as the thickness of the second electrode 16 in a main acoustically active region of the BAW device 1. In some embodiments, the first and second layers 16a, 16b of the second electrode 16 can have the same material or different materials. In some embodiments, the first layer 16a and the second layer 16b of the second electrode 16 can be connected to one another. In some embodiments, the second layer 16b can be electrically floating.

The piezoelectric layer 14 is positioned between the first electrode 12 and the second electrode 16. The piezoelectric layer 14 can include aluminum nitride, zinc oxide, or any other suitable piezoelectric material. The piezoelectric layer 14 can be doped with any suitable dopant, such as scandium (Sc), chromium (Cr), magnesium (Mg), sulfur (S), yttrium (Y), silicon (Si), germanium (Ge), oxygen (O), hafnium (Hf), zirconium (Zr), titanium (Ti), or the like. In certain instances, the piezoelectric layer 14 can be an aluminum nitride layer doped with scandium. Doping the piezoelectric layer 14 can adjust resonant frequency. Doping the piezoelectric layer 14 can increase the coupling coefficient k² of the BAW device 1. Doping to increase the coupling coefficient k² can be advantageous at higher frequencies where the coupling coefficient k² can be degraded.

The temperature compensation layer 18 can bring the temperature coefficient of frequency (TCF) of the BAW device 1 closer to zero relative to a similar acoustic wave device without the temperature compensation layer. The temperature compensation layer 18 can have a positive temperature coefficient of elasticity (TCE). The temperature compensation layer 18 can compensate for the piezoelectric layer 14 having a negative TCE. The temperature compensation layer 18 can include any suitable material that has a positive TCE. For example, the temperature compensation layer 18 can include silicon oxide (e.g., silicon dioxide (SiO₂)). Silicon dioxide can also be referred to as amorphous silica or fused silica. Silicon dioxide is a material with an acoustic velocity and an elastic modulus that increase with temperature. Such characteristics of Silicon dioxide can allow for temperature compensation with piezoelectric materials that have an acoustic velocity and an elastic modulus that decrease with temperature. In conventional temperature compensated bulk acoustic wave (TC-BAW) devices, a silicon oxide layer is positioned between and in contact with a piezoelectric layer and an electrode as such position can generate more heat than other portions of the TC-BAW devices and positioning the silicon oxide layer at other locations may not provide sufficient temperature compensation. The temperature compensation layer 18 can be doped to increase the TCF. For example, the temperature compensation layer 18 can include silicon oxide doped with fluorine (F), phosphorus (P), boron (B), or nitrogen (N).

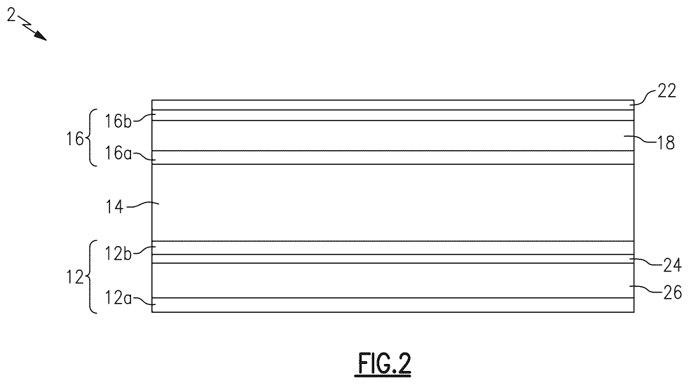

In various embodiments disclosed herein, the temperature compensation layer 18 is provided between the first and second layers 16a, 16b of the second electrode 16. The temperature compensation layer 18 can also be referred to as an intervening layer. The first layer 16a can be positioned between the piezoelectric layer 14 and the temperature compensation layer 18 such that the temperature compensation layer 18 does not directly contact the piezoelectric layer 14. The temperature compensation layer 18 can be positioned outside of a region between the first layer 16a and the first electrode 12. In some embodiments, the temperature compensation layer 18 can be physically isolated from the piezoelectric layer 14 such that the temperature compensation layer 18 and the piezoelectric layer 14 do not have the same or generally the same electric field. In some embodiments, at least a portion of the second electrode structure can isolate the temperature compensation layer 18 from the piezoelectric layer 14. As the temperature compensation layer 18 is not disposed between the first electrode 12 and the first layer 16a, there can be no or almost no electric field applied to the temperature compensation layer 18 or a significantly lower electric field applied to the temperature compensation layer 18 than to the piezoelectric layer 14. For example, the electric field in the temperature compensation layer 18 can be in a range of 0% to 25%, 0% to 15%, 0% to 5%, 0% to 3%, or 0% to 0.1% of the electric field in the piezoelectric layer 14. In some embodiments, the second electrode 16 can include more than two conductive layers with a temperature compensation layer 18 therebetween. In some embodiments, the first electrode 12 can include two or more conductive layers (see FIG. 2).

The first passivation layer 20 can include any material that functions as a passivation layer. The first passivation layer 20 can be a dielectric layer. In some embodiments, the first passivation layer 20 can be a silicon oxycarbide layer, a silicon dioxide layer, or any other suitable passivation layer. The first passivation layer 20 can, for example, protect the first electrode 12 during a sacrificial layer removal process for removing a sacrificial layer. In some embodiments, the first passivation layer 20 can include a micro electromechanical system (MEMS) layer.

The second passivation layer 22 can include any material that functions as a passivation layer. The second passivation layer 22 can function as both passivation and frequency trimming or frequency adjustment. Therefore, the second passivation layer 22 can be referred to as a frequency adjustment or trimming layer. The second passivation layer 22 can be a dielectric layer. In some embodiments, the second passivation layer 22 can be a silicon oxycarbide layer, a silicon dioxide layer, or any other suitable passivation layer.

The seed layer 24 can be in contact with the second electrode 16 and the frequency adjustment layer 18. The seed layer 24 can be a seed layer for forming the first electrode 12. In some embodiments, the seed layer 24 can include a piezoelectric material. For example, the seed layer 24 can include the same material as the material of the piezoelectric layer 14. The seed layer 24 can be referred to as a bonding layer.

Thicknesses of the layers in the BAW device 1 can be optimized based at least in part on desired operation mode, frequency, and coupling coefficient k². The temperature compensation layer 18 can have less acoustic velocity than the piezoelectric layer 14 and the wave shapes of the fundamental mode and the second overtone mode can, for example, be as shown in FIG. 1. In some applications, the thicknesses of the layers in the BAW device 1 can be optimized for operating in the fundamental mode at a frequency of 3.2 GHz with 2.1% as the coupling coefficient k². In some other applications, the thicknesses of the layers in the BAW device 1 can be optimized for operating in the second overtone mode at a frequency of 5.9 GHz with 6.1% as the coupling coefficient k². In case of the second overtone mode, during operation, when the piezoelectric layer 14 compresses, the temperature compensation layer 18 can expand, and when the piezoelectric layer 14 expands, the temperature compensation layer 18 can compress.

In some embodiments, the first electrode 12 can have a thickness in a range between 30 nm and 120 nm, 50 nm and 100 nm, 60 nm and 90 nm, or 70 nm and 80 nm. In some embodiments, the piezoelectric layer 14 can have a thickness in a range between 300 nm and 550 nm, 360 nm and 500 nm, 390 nm and 470 nm, or 420 nm and 440 nm. In some embodiments, the first layer 16a of the second electrode 16 can have a thickness in a range between 20 nm and 150 nm, 40 nm and 130 nm, 60 nm and 110 nm, or 80 nm and 90 nm. In some embodiments, the second layer 16b of the second electrode 16 can have a thickness in a range between 10 nm and 110 nm, 20 nm and 100 nm, 30 nm and 90 nm, or 55 nm and 65 nm. In some embodiments, the temperature compensation layer 18 can have a thickness in a range between 5 nm and 300 nm, 75 nm and 300 nm, 80 nm and 260 nm, 100 nm and 240 nm, 130 nm and 210 nm, or 160 nm and 180 nm. In some embodiments, the first passivation layer 20 can have a thickness in a range between 30 nm and 70 nm, 40 nm and 60 nm, or 45 nm and 55 nm. In some embodiments, the second passivation layer 22 can have a thickness in a range between 30 nm and 70 nm, 40 nm and 60 nm, or 45 nm and 55 nm. In some embodiments, the seed layer 24 can have a thickness in a range between 20 nm and 60 nm, 30 nm and 50 nm, or 35 nm and 45 nm.

FIG. 1 shows that the second electrode 16 includes the first layer 16a and the second layer 16b and the temperature compensation layer 18 is provided between the first layer 16a and the second layer 16b to form the second electrode structure. In some other embodiments, the first electrode 12 can have a multilayer structure with a temperature compensation layer provided therebetween to form a first electrode structure, as shown in FIG. 2.

FIG. 2 is a schematic cross-sectional side view of a bulk acoustic wave (BAW) device 2 according to an embodiment. The BAW device 2 can include a first electrode 12, a piezoelectric layer 14 over the first electrode 12, and a second electrode 16 over the piezoelectric layer 14. The first electrode 12 can include a first layer 12a and a second layer 12b. The second electrode 16 can include a first layer 16a and a second layer 16b. The BAW device 2 can also include a temperature compensation layer 26 between the first and second layers 12a, 12b, a temperature compensation layer 18 between the first and second layers 16a, 16b, a passivation layer 22, and a seed layer 24. The first layer 12a, the second layer 12b, and the temperature compensation layer 26 can together at least partially define a first electrode structure. The first layer 16a, the second layer 16b, and the temperature compensation layer 18 can together at least partially define a second electrode structure. Unless otherwise noted, the components of the BAW device 2 shown in FIG. 2 may be structurally and/or functionally the same as or generally similar to like components of the BAW device 1 of FIG. 1.

The temperature compensation layer 26 can bring the temperature coefficient of frequency (TCF) of the BAW device 2 closer to zero relative to a similar acoustic wave device without the temperature compensation layer. The temperature compensation layer 26 can have a positive TCE. The temperature compensation layer 26 can compensate for the piezoelectric layer 14 having a negative TCE. The temperature compensation layer 26 can include any suitable material that has a positive TCE. For example, the temperature compensation layer 26 can include silicon oxide (e.g., silicon dioxide (SiO₂)). Silicon dioxide can also be referred to as amorphous silica or fused silica. Silicon dioxide is a material with an acoustic velocity and an elastic modulus that increase with temperature. Such characteristics of Silicon dioxide can allow for temperature compensation with piezoelectric materials that have an acoustic velocity and an elastic modulus that decrease with temperature. In conventional temperature compensated bulk acoustic wave (TC-BAW) devices, a silicon oxide layer is positioned between and in contact with a piezoelectric layer and an electrode as such position can generate more heat than other portions of the TC-BAW devices and positioning the silicon oxide layer at other locations may not provide sufficient temperature compensation. The temperature compensation layer 26 can be doped to increase the TCE. For example, the temperature compensation layer 26 can include silicon oxide doped with fluorine (F), phosphorus (P), boron (B), or nitrogen (N).

In FIG. 2, the first and second electrode structures are illustrated to include two layers (the first and second layers 12a, 12b, 16a, 16b) each with an intervening temperature layer (the temperature layers 18, 26). However, there may be more layers with more intervening temperature compensation layers. Incorporating more temperature compensation layers may be beneficial for providing higher order mode BAW devices.

The structures of the BAW devices 1, 2 shown in FIGS. 1 and 2 can be provided over a support structure. The support structure can include a cavity and the BAW device can be a film bulk acoustic wave resonator (FBAR) (see FIG. 3), or the support structure can include a solid acoustic mirror and the BAW device 1 can be a BAW solidly mounted resonator (SMR) (see FIG. 4).

FIG. 3 is a schematic cross-sectional side view of the BAW device 1 disposed on a support structure 30 as an example of a film bulk acoustic wave resonator (FBAR). Unless otherwise noted, the components of the BAW device 3 shown in FIG. 3 may be structurally and/or functionally the same as or generally similar to like components of the BAW device 1 of FIG. 1.

The support substrate can include a cavity 32. The cavity 32 can be an air cavity. In some embodiments, the support structure 30 can have a multi-layer structure. For example, the support structure can include a support substrate (e.g., a semiconductor substrate such as a silicon substrate), a trap rich layer (not shown), a passivation layer 20, or one or more intermediate layers therebetween (not shown).

FIG. 4 is a schematic cross-sectional side view of the BAW device 1 disposed on a support structure 40 as an example of a BAW solidly mounted resonator (SMR). Unless otherwise noted, the components of the BAW device 4 shown in FIG. 4 may be structurally and/or functionally the same as or generally similar to like components of the BAW device 1 of FIG. 1.

The support structure 40 can include a support substrate 42 and a solid acoustic mirror 45. The illustrated acoustic mirror 45 includes acoustic Bragg reflectors. The illustrated acoustic Bragg reflectors can include alternating low impedance layers 46 and high impedance layers 48. As an example, the Bragg reflectors can include alternating silicon dioxide layers as low impedance layers 46 and tungsten layers as high impedance layers 48. Any other suitable features of an SMR can alternatively or additionally be implemented.

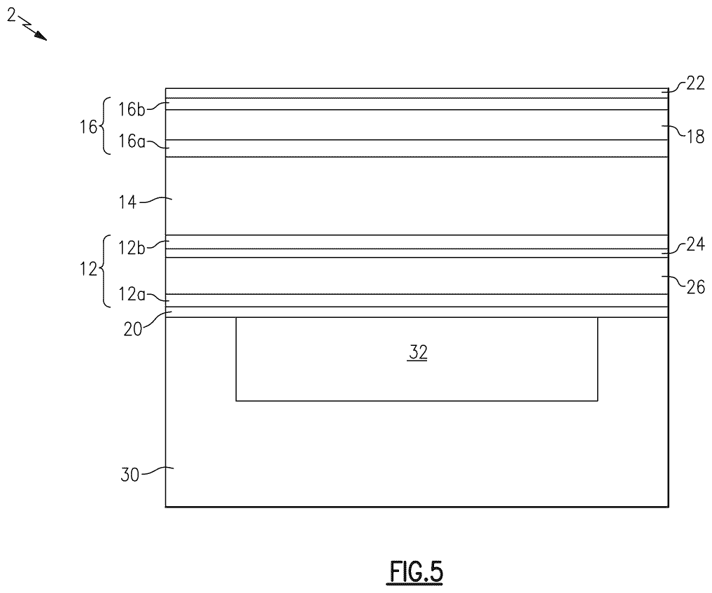

A skilled artisan will understand that the BAW device 2 shown in FIG. 2 can also be disposed over a support structure in any suitable manner. For example, the BAW device 2 can be disposed over the support structure 30 as shown in FIG. 5, or be disposed over the support structure 40.

The electrode structures disclosed herein that include a temperature compensation layer between two or more conductive layers of an electrode can be beneficial for providing an improved temperature coefficient of frequency (TCF), an improved coupling coefficient k², and/or a higher-order mode operation device.

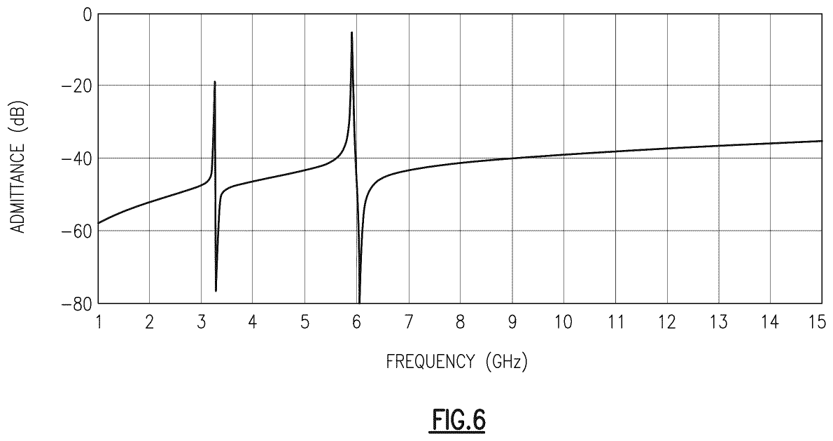

FIG. 6 is a graph showing a simulated frequency response of the BAW device 1 according to an embodiment. The BAW device 1 used in the simulation configured to operate in the second overtone mode at a frequency of 5.9 GHz with 6.1% as the coupling coefficient k². In the BAW device used in the simulation, the first electrode 12 has a thickness of 75 nm, the piezoelectric layer 14 has a thickness of 430 nm, the first layer 16a of the second electrode 16 has a thickness of 85 nm, the second layer 16b of the second electrode 16 has a thickness of 60 nm, the temperature compensation layer 18 has a thickness of 170 nm, the first passivation layer 20 has a thickness of 50 nm, the second passivation layer 22 has a thickness of 50 nm, and the seed layer 24 has a thickness of 40 nm.

The graph indicates that the electrode structure (e.g., the combination of the first layer 12a, the second layer 12b, and the temperature compensation layer 18) can enable the BAW device 1 to operate at the second overtone mode and provide a temperature coefficient of frequency (TCF) relatively close to zero (TCF_{fs}=−3.8 ppm/° C. and TCF_{fp}=−8.1 ppm/° C.) and to have a relatively high coupling coefficient k² (6.1%).

In some embodiments, a module that implements a BAW device in accordance with various embodiments disclosed herein can implement a filter, such as a notch filter (e.g., an LC notch filter) to attenuate or reject a specific narrow range of frequencies. For example, the notch filter can be used with a BAW device that operates at the second overtone mode to reject the fundamental mode.

A method of forming a bulk acoustic wave device (e.g., the BAW device 1, 2 disclosed herein) according to an embodiment can include providing a first electrode 12, providing a piezoelectric layer 14 over the first electrode 12, providing a second electrode 16 including a first layer 16a and a second layer 16b such that the piezoelectric layer 14 is positioned between the first and second electrodes 12, 16, and providing a temperature compensation layer 18 between the first and second layers 16a, 16b of the second electrode. Providing the temperature compensation layer can include depositing the temperature compensation layer over the first layer of the second electrode. The second layer can be deposited over the temperature compensation layer. The method can further include providing a passivation layer 22 over the second layer 16b such that the second layer 16b is positioned between the temperature compensation layer 14 and the passivation layer 22. The piezoelectric layer can be provided in a manner so that the piezoelectric layer contacts the first layer 16a of the second electrode 16 and/or the first electrode 12.

A method of forming a bulk acoustic wave device (e.g., the BAW device 1, 2 disclosed herein) according to an embodiment can include providing a first electrode structure, providing a piezoelectric layer 14 over the first electrode structure, and providing a second electrode structure such that the piezoelectric layer is positioned between the first and second electrodes. The first electrode structure can include a first electrode 12 including first and second layers 12a, 12b and an intervening layer (e.g., the temperature compensation layer 26) between the first layer 12a and the second layer 12b. The second electrode structure can include a second electrode 16 including first and second layers 16a, 16b, and an intervening layer (e.g., the temperature compensation layer 18) between the first layer 16a and the second layer 16b. The piezoelectric layer 14 is physically isolated from the intervening layer. The intervening layer can be positioned outside of a region between the first layer 16a of the second electrode structure and the first electrode structure. The method can further include providing a passivation layer 22 over the second layer 16b of the second electrode structure such that the second layer 16b is positioned between the intervening layer and the passivation layer 22.

The bulk acoustic wave resonators disclosed herein can be implemented in acoustic wave filters. In certain applications, the acoustic wave filters can be band pass filters arranged to pass a radio frequency band and attenuate frequencies outside of the radio frequency band. Two or more acoustic wave filters can be coupled together at a common node and arranged as a multiplexer, such as a duplexer.

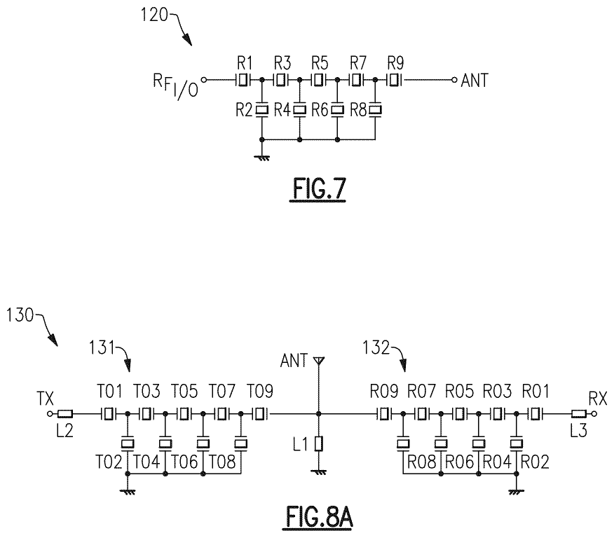

FIG. 7 is a schematic diagram of an example of an acoustic wave ladder filter 120. The acoustic wave ladder filter 120 can be a transmit filter or a receive filter. The acoustic wave ladder filter 120 can be a band pass filter arranged to filter a radio frequency signal. The acoustic wave filter 120 includes series resonators R1, R3, R5, R7, and R9 and shunt resonators R2, R4, R6, and R8 coupled between a radio frequency input/output port RF_{I/O} and an antenna port ANT. The radio frequency input/output port RF_{I/O} can be a transmit port in a transmit filter or a receive port in a receive filter. One or more of the illustrated acoustic wave resonators can be a bulk acoustic wave resonator in accordance with any suitable principles and advantages discussed herein. An acoustic wave ladder filter can include any suitable number of series resonators and any suitable number of shunt resonators.

An acoustic wave filter can be arranged in any other suitable filter topology, such as a lattice topology or a hybrid ladder and lattice topology. A bulk acoustic wave resonator in accordance with any suitable principles and advantages disclosed herein can be implemented in a band pass filter. In some other applications, a bulk acoustic wave resonator in accordance with any suitable principles and advantages disclosed herein can be implemented in a band stop filter.

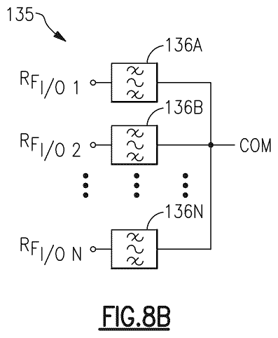

FIG. 8A is a schematic diagram of an example of a duplexer 130. The duplexer 130 includes a transmit filter 131 and a receive filter 132 coupled to each other at an antenna node ANT. A shunt inductor L1 can be connected to the antenna node ANT. The transmit filter 131 and the receive filter 132 are both acoustic wave ladder filters in the duplexer 130.

The transmit filter 131 can filter a radio frequency signal and provide a filtered radio frequency signal to the antenna node ANT. A series inductor L2 can be coupled between a transmit input node TX and the acoustic wave resonators of the transmit filter 131. The illustrated transmit filter 131 includes acoustic wave resonators T01 to T09. One or more of these resonators can be a bulk acoustic wave resonator in accordance with any suitable principles and advantages disclosed herein. The illustrated receive filter includes acoustic wave resonators RO1 to R09. One or more of these resonators can be a bulk acoustic wave resonator in accordance with any suitable principles and advantages disclosed herein. The receive filter can filter a radio frequency signal received at the antenna node ANT. A series inductor L3 can be coupled between the resonator and a receive output node RX. The receive output node RX of the receive filter provides a radio frequency receive signal.

FIG. 8B is a schematic diagram of a multiplexer 135 that includes an acoustic wave filter according to an embodiment. The multiplexer 135 includes a plurality of filters 136A to 136N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. Each of the illustrated filters 136A, 136B, and 136N is coupled between the common node COM and a respective input/output node RF_{I/O1}, RF_{I/O2}, and RF_{I/ON}.

In some instances, all filters of the multiplexer 135 can be receive filters. According to some other instances, all filters of the multiplexer 135 can be transmit filters. In various applications, the multiplexer 135 can include one or more transmit filters and one or more receive filters. Accordingly, the multiplexer 135 can include any suitable number of transmit filters and any suitable number of receive filters. Each of the illustrated filters can be band pass filters having different respective pass bands.

The multiplexer 135 is illustrated with hard multiplexing with the filters 136A to 136N having fixed connections to the common node COM. In some other applications, one or more of the filters of a multiplexer can be electrically connected to the common node by a respective switch. Any of such filters can include a bulk acoustic wave resonator according to any suitable principles and advantages disclosed herein.

A first filter 136A is an acoustic wave filter having a first pass band and arranged to filter a radio frequency signal. The first filter 136A can include one or more bulk acoustic wave resonators according to any suitable principles and advantages disclosed herein. A second filter 136B has a second pass band. In certain instances, the common node COM of the multiplexer 135 is arranged to receive a carrier aggregation signal including at least a first carrier associated with the first passband of the first filter 136A and a second carrier associated with the second passband of the second filter 136B.

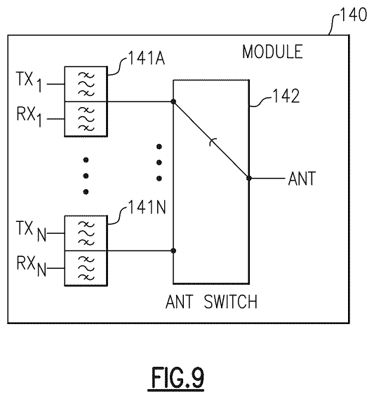

The bulk acoustic wave resonators disclosed herein can be implemented in a variety of packaged modules. Some example packaged modules will now be discussed in which any suitable principles and advantages of the bulk acoustic wave devices disclosed herein can be implemented. The example packaged modules can include a package that encloses the illustrated circuit elements. The illustrated circuit elements can be disposed on a common packaging substrate. The packaging substrate can be a laminate substrate, for example. FIGS. 9-11 are schematic block diagrams of illustrative packaged modules according to certain embodiments. Certain example packaged modules include one or more radio frequency amplifiers, such as one or more power amplifiers and/or one or more low noise amplifiers. Any suitable combination of features of these modules can be implemented with each other. While duplexers are illustrated in some examples packaged modules, any other suitable multiplexer that includes a plurality of acoustic wave filters coupled to a common node can be implemented instead of one or more duplexers. For example, a quadplexer can be implemented in certain applications. Alternatively or additionally, one or more filters of a packaged module can be arranged as a transmit filter or a receive filter that is not included in a multiplexer.

FIG. 9 is a schematic block diagram of a module 140 that includes duplexers 141A to 141N and an antenna switch 142. One or more filters of the duplexers 141A to 141N can include any suitable number of bulk acoustic wave resonators in accordance with any suitable principles and advantages discussed herein. Any suitable number of duplexers 141A to 141N can be implemented. The antenna switch 142 can have a number of throws corresponding to the number of duplexers 141A to 141N. The antenna switch 142 can electrically couple a selected duplexer to an antenna port of the module 140.

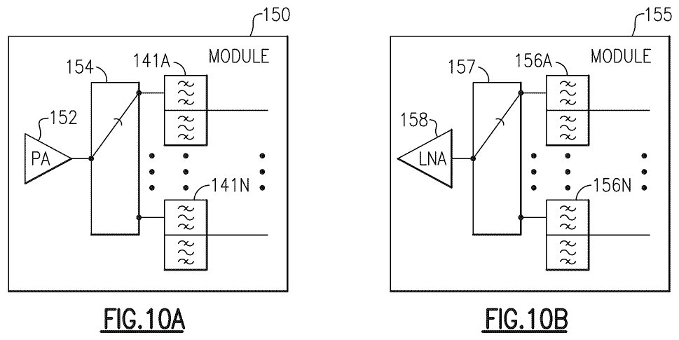

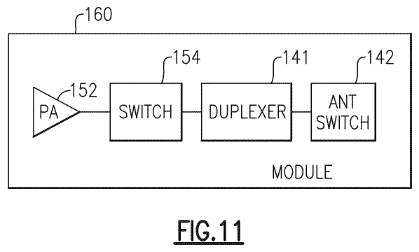

FIG. 10A is a schematic block diagram of a module 150 that includes a power amplifier 152, a radio frequency switch 154, and duplexers 141A to 141N in accordance with one or more embodiments. The power amplifier 152 can amplify a radio frequency signal. The radio frequency switch 154 can be a multi-throw radio frequency switch. The radio frequency switch 154 can electrically couple an output of the power amplifier 152 to a selected transmit filter of the duplexers 141A to 141N. One or more filters of the duplexers 141A to 141N can include any suitable number of bulk acoustic wave resonators in accordance with any suitable principles and advantages discussed herein. Any suitable number of duplexers 141A to 141N can be implemented.

FIG. 10B is a schematic block diagram of a module 155 that includes filters 156A to 156N, a radio frequency switch 157, and a low noise amplifier 158 according to an embodiment. One or more filters of the filters 156A to 156N can include any suitable number of bulk acoustic wave resonators in accordance with any suitable principles and advantages disclosed herein. Any suitable number of filters 156A to 156N can be implemented. The illustrated filters 156A to 156N are receive filters. In some embodiments (not illustrated), one or more of the filters 156A to 156N can be included in a multiplexer that also includes a transmit filter. The radio frequency switch 157 can be a multi-throw radio frequency switch. The radio frequency switch 157 can electrically couple an output of a selected filter of filters 156A to 156N to the low noise amplifier 158. In some embodiments (not illustrated), a plurality of low noise amplifiers can be implemented. The module 155 can include diversity receive features in certain applications.

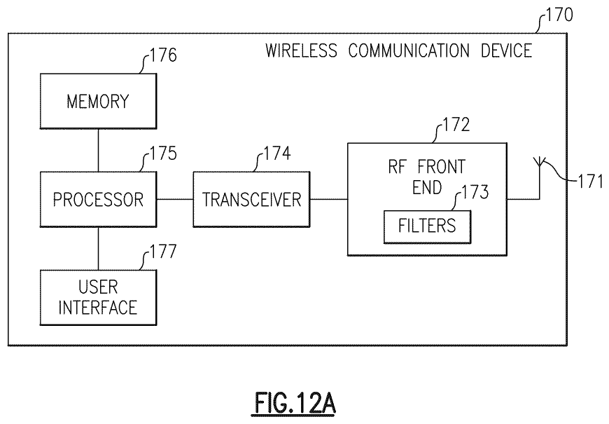

FIG. 11 is a schematic block diagram of a module 160 that includes a power amplifier 152, a radio frequency switch 154, and a duplexer 141 that includes a bulk acoustic wave device in accordance with one or more embodiments, and an antenna switch 142. The module 160 can include elements of the module 140 and elements of the module 150.

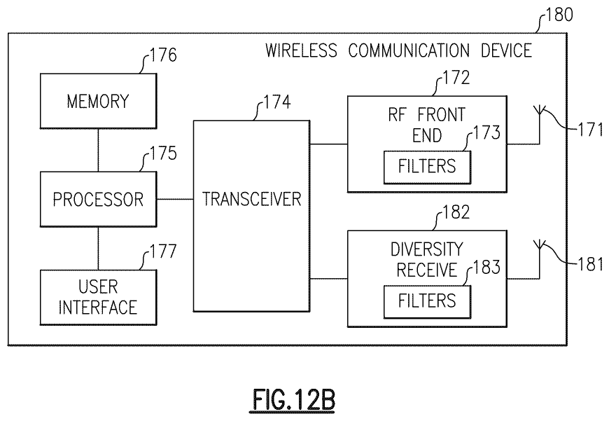

One or more filters with any suitable number of bulk acoustic devices can be implemented in a variety of wireless communication devices. FIG. 12A is a schematic block diagram of a wireless communication device 170 that includes a filter 173 with one or more bulk acoustic wave resonators in accordance with any suitable principles and advantages disclosed herein. The wireless communication device 170 can be any suitable wireless communication device. For instance, a wireless communication device 170 can be a mobile phone, such as a smart phone. As illustrated, the wireless communication device 170 includes an antenna 171, a radio frequency (RF) front end 172 that includes filter 173, an RF transceiver 174, a processor 175, a memory 176, and a user interface 177. The antenna 171 can transmit RF signals provided by the RF front end 172. The antenna 171 can provide received RF signals to the RF front end 172 for processing.

The RF front end 172 can include one or more power amplifiers, one or more low noise amplifiers, RF switches, receive filters, transmit filters, duplex filters, filters of a multiplexer, filters of a diplexers or other frequency multiplexing circuit, or any suitable combination thereof. The RF front end 172 can transmit and receive RF signals associated with any suitable communication standards. Any of the bulk acoustic wave resonators disclosed herein can be implemented in filters 173 of the RF front end 172.

The RF transceiver 174 can provide RF signals to the RF front end 172 for amplification and/or other processing. The RF transceiver 174 can also process an RF signal provided by a low noise amplifier of the RF front end 172. The RF transceiver 174 is in communication with the processor 175. The processor 175 can be a baseband processor. The processor 175 can provide any suitable base band processing functions for the wireless communication device 170. The memory 176 can be accessed by the processor 175. The memory 176 can store any suitable data for the wireless communication device 170. The processor 175 is also in communication with the user interface 177. The user interface 177 can be any suitable user interface, such as a display.

FIG. 12B is a schematic diagram of a wireless communication device 180 that includes filters 173 in a radio frequency front end 172 and second filters 183 in a diversity receive module 182. The wireless communication device 180 is like the wireless communication device 170 of FIG. 12A, except that the wireless communication device 180 also includes diversity receive features. As illustrated in FIG. 12B, the wireless communication device 180 includes a diversity antenna 181, a diversity module 182 configured to process signals received by the diversity antenna 181 and including filters 183, and a transceiver 174 in communication with both the radio frequency front end 172 and the diversity receive module 182. One or more of the second filters 183 can include a bulk acoustic wave resonator in accordance with any suitable principles and advantages disclosed herein.

Bulk acoustic wave devices disclosed herein can be included in a filter and/or a multiplexer arranged to filter a radio frequency signal in a fifth generation (5G) New Radio (NR) operating band within Frequency Range 1 (FR1). FR1 can from 410 megahertz (MHz) to 7.125 gigahertz (GHz), for example, as specified in a current 5G NR specification. A filter arranged to filter a radio frequency signal in a 5G NR FR1 operating band can include one or more bulk acoustic wave resonators in accordance with any suitable principles and advantages disclosed herein.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz.

An acoustic wave filter including any suitable combination of features disclosed herein can be arranged to filter a radio frequency signal in a fifth generation (5G) New Radio (NR) operating band within Frequency Range 1 (FR1). A filter arranged to filter a radio frequency signal in a 5G NR operating band can include one or more devices of any of the stacked device arrangements disclosed herein. FR1 can be from 410 MHz to 7.125 GHz, for example, as specified in a current 5G NR specification. One or more acoustic wave filters in accordance with any suitable principles and advantages disclosed herein can be arranged to filter a radio frequency signal in a fourth generation (4G) Long Term Evolution (LTE) operating band and/or in a filter with a passband that spans a 4G LTE operating band and a 5G NR operating band.

Aspects of this disclosure can be implemented in various electronic devices. Examples of the electronic devices can include, but are not limited to, consumer electronic products, parts of the consumer electronic products such as die and/or acoustic wave components and/or acoustic wave filter assemblies and/or packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a personal digital assistant (PDA), a microwave, a refrigerator, an automobile, a stereo system, a DVD player, a CD player, a digital music player such as an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device comprising:
a first electrode;
a second electrode including a first layer and a second layer;
a piezoelectric layer between the first and second electrodes; and
a temperature compensation layer between the first and second layers of the second electrode.

2. The bulk acoustic wave device of claim 1 wherein the piezoelectric layer is in contact with the first electrode and the first layer of the second electrode.

3. The bulk acoustic wave device of claim 1 wherein the second layer is electrically floating.

4. The bulk acoustic wave device of claim 1 wherein the second layer is electrically connected to the first layer.

5. The bulk acoustic wave device of claim 1 wherein the first layer and the second layer include the same material.

6. The bulk acoustic wave device of claim 1 wherein the first layer and the second layer have different thicknesses.

7. The bulk acoustic wave device of claim 1 further comprising a passivation layer over the second layer such that the second layer is positioned between the temperature compensation layer and the passivation layer.

8. The bulk acoustic wave device of claim 1 wherein the temperature compensation layer includes silicon oxide.

9. The bulk acoustic wave device of claim 1 wherein the temperature compensation layer has a thickness in a range between 5 nanometers and 300 nanometers.

10. The bulk acoustic wave device of claim 1 wherein the first electrode includes a third layer and a fourth layer, the third layer is in contact with the piezoelectric layer and a second temperature compensation layer is disposed between the third and fourth layers.

11. The bulk acoustic wave device of claim 1 wherein thicknesses of the piezoelectric layer and the temperature compensation layer are configured to excite a fundamental mode as a main mode.

12. The bulk acoustic wave device of claim 1 wherein thicknesses of the piezoelectric layer and the temperature compensation layer are configured to excite an overtone mode as a main mode.

13. The bulk acoustic wave device of claim 12 wherein a resonant frequency of the overtone mode is in a range from 5 gigahertz to 12 gigahertz.

14. The bulk acoustic wave device of claim 12 wherein the overtone mode is a second overtone mode.

15. A method of forming a bulk acoustic wave device, the method comprising:
providing a first electrode;
providing a piezoelectric layer over the first electrode;
providing a second electrode including a first layer and a second layer such that the piezoelectric layer is positioned between the first and second electrodes; and
providing a temperature compensation layer between the first and second layers of the second electrode.

16. The method of claim 15 wherein providing the temperature compensation layer includes depositing the temperature compensation layer over the first layer of the second electrode.

17. The method of claim 15 wherein the temperature compensation layer includes silicon oxide.

18. The method of claim 15 further comprising providing a passivation layer over the second layer such that the second layer is positioned between the temperature compensation layer and the passivation layer.

19. The method of claim 15 wherein the piezoelectric layer contacts the first layer of the second electrode.

20. The method of claim 15 wherein the piezoelectric layer contacts the first layer of the second electrode.
